(19) United States
(12) Patent Application Publication
(10) Pub. No.: US 2026/0372007 A1
(43) Pub. Date: Nov. 19, 2026

(54) POSITION GUIDING MEMBER, APPARATUS FOR TRANSPORTING SUBSTRATE INCLUDING THE SAME AND METHOD FOR POSITION GUIDING OF SUBSTRATE

(71) Applicant: KCTECH CO., LTD., Gyeonggi-do (KR)

(72) Inventors: Yun Seok LEE, Gyeonggi-do (KR); Dong Hwa LEE, Gyeonggi-do (KR); Seung Kyo KIM, Gyeonggi-do (KR)

(21) Appl. No.: 19/675,724

(22) Filed: May 13, 2026

(30) Foreign Application Priority Data
May 14, 2025 (KR) 10-2025-0062755

(51) Int. Cl. H10P 72/50; B25J 11/00; B25J 15/00; H10P 72/76

(52) U.S. Cl. CPC H10P 72/50; B25J 11/0095; H10P 72/7602; B25J 15/0014

(57) ABSTRACT

Disclosed is a position guiding member comprising a first body having a first width of a circumferential shape; a plurality of second bodies having a second width to connect facing points of the first body; a plurality of friction reducing members provided on a first surface of the second body; and a position fixing member provided in an area where the first body and the second body meet and provided with at least a portion protruding to the outside of the first body.

### CROSS-REFERENCE TO RELATED APPLICATIONS

This application claims the benefit of the Korean Patent Applications No. 10-2025-0062755 filed on May 14, 2025, which are hereby incorporated by reference as if fully set forth herein.

### FIELD

The present disclosure relates to a position guiding member, an apparatus for transporting a substrate including the same, and a method for position guiding of substrate, and more particularly, to a position guiding member capable of placing a substrate at an accurate position inside a chamber during loading of substrate in a processing process of substrate with a supercritical fluid, an apparatus for transporting a substrate including the same, and a method for position guiding of substrate.

### BACKGROUND

A semiconductor is produced through a processing process such as a deposition process of depositing a thin film of a specific material on a substrate, a photo process of selectively exposing the thin film using a photosensitive material, and an etching process of forming a pattern by removing the thin film of the selectively exposed portion. In this case, impurities such as metal, particles, and organic matters generated during the processing process have an important effect on yield and quality of the semiconductor. To this end, a cleaning process and a drying process of removing the impurities from the substrate are required.

A supercritical substrate processing apparatus is provided to perform the drying process on the substrate in which the cleaning process is completed. The drying process is to dry a cleaning solution on the substrate in which the cleaning process is completed. Herein, the supercritical substrate processing apparatus may dry an anti-drying solution coated onto the substrate in the cleaning process. The supercritical substrate processing apparatus may spray the anti-drying solution corresponding to a fluid in a supercritical state, and may dry the anti-drying solution (hereinafter, referred to as “organic solvent”) coated onto the substrate. This drying process may be performed in a high-temperature and high-pressure chamber.

When the drying process or the cleaning process is performed, it is needed to align the substrate at an accurate position of the chamber.

In the related art, a substrate transporting apparatus referred to as a robot end effector is used. After the substrate transporting apparatus on which a substrate is supported is loaded into the inside of a chamber, and a worker checks whether or not the substrate is aligned on a substrate supporter referred to as a chuck plate with the naked eye from the outside of the chamber, only the substrate transporting apparatus is unloaded from the chamber to the outside.

At this time, when it is checked whether the substrate is aligned on the chuck plate only by the naked eye of the worker, an error may occur due to a worker's mistake, and particles may generate due to a collision between a wafer and a member such as the chuck plate.

### SUMMARY

Therefore, the present disclosure has been made in view of the above problems, and it is an object of the present disclosure to place a substrate at an accurate position inside a chamber during loading of substrate in a processing process of substrate with a supercritical fluid.

An embodiment of the present disclosure provides a position guiding member comprising a first body having a first width of a circumferential shape; a plurality of second bodies having a second width to connect facing points of the first body; a plurality of friction reducing members provided on a first surface of the second body; and a position fixing member provided in an area where the first body and the second body meet and provided with at least a portion protruding to the outside of the first body.

The friction reducing members may be provided on a first surface of the position fixing member.

One pair of the position fixing members may be provided, and a first distance between the pair of position fixing members may be the same as a diameter of the first body.

The plurality of second bodies may include a (2-1)th body provided in the X-axis direction and a (2-2)th body provided in the Y-axis direction.

The pair of position fixing members may be respectively provided in areas where the first body and the (2-1)th body meet.

The position guiding member may further comprise a capacitance sensor provided in one area where the first body and the (2-2)th body meet.

The plurality of friction reducing members may include a reduction body, and a spherical member inserted into a lower portion of the reducing body and exposed thereto.

The position guiding member may further comprise an elastic member inserted into the inside of the reducing body.

The position guiding member may further comprise a first coupling member provided on both sides of the spherical member and configured to couple the reducing body to the first surface of the second body.

Another embodiment of the present disclosure provides an apparatus for transporting a substrate comprising an arm connected to a transporting robot; a pair of support members connected to the arm and configured to support and transport a substrate; and a position guiding member provided on the support member and described above, wherein a first surface of a first body and a first surface of a second body in the position guiding member are in contact with an upper surface of the support member.

A stopper may be provided in each of the pair of support members, and the first body of the position guiding member may be in contact with the stopper.

A capacitance sensor, which is provided in one area where the first body and the (2-2)th body of the position guiding member meet, may be provided on the first surface of the first body in an area facing the transporting robot.

The plurality of second bodies of the position guiding member may include the (2-1)th body provided in the X-axis direction and the (2-2)th body provided in the Y-axis direction, and the (2-1)th body may be disposed in a direction connecting the pair of support members.

Another embodiment of the present disclosure provides a method for position guiding of substrate comprising a step of preparing an apparatus for transporting a substrate in which a position guiding member for guiding a placement position of a substrate is disposed on a pair of support members connected to an arm; a step of loading the apparatus for transporting a substrate into a substrate processing chamber; and a step of positioning the position guiding member on a chuck plate on which the substrate is to be placed inside the chamber, wherein the position guiding member includes a first body having a first width of a circumferential shape corresponding to an edge area of the substrate, and a position fixing member provided on a first surface of the first body and provided with at least a portion protruding to the outside of the first body, and a first guide pin provided on the chuck plate is in contact with the position fixing member in the step of positioning the position guiding member on the chuck plate on which the substrate is to be placed inside the apparatus for transporting a substrate.

One pair of the position fixing members may be provided, and the position fixing members and the first guide pins provided on the chuck plate may be in contact with each other on both sides of the area on which the substrate is to be placed in the step of positioning the position guiding member on the chuck plate on which the substrate is to be placed inside the apparatus for transporting a substrate.

A plurality of friction reducing members may be provided on a rear surface of the guide member, and the position guiding member may slide on the chuck plate to bring the friction reducing members into contact with the chuck plate in the step of positioning the position guiding member on the chuck plate on which the substrate is to be placed inside the apparatus for transporting a substrate.

The plurality of friction reducing members may include a reducing body and a spherical member inserted to a lower portion of the reducing body and exposed thereto, and the spherical member may be in contact with the chuck plate when the position guiding member slides on the chuck plate.

The position guiding member further may include a capacitance sensor provided at the foremost side of the first body, and the capacitance sensor may sense a back plate provided on a lower portion of the chuck plate in the step of positioning the position guiding member on the chuck plate on which the substrate is to be placed inside the apparatus for transporting a substrate.

A stopper may be provided in each of the pair of support members of the apparatus for transporting a substrate, and the first body of the position guiding member may be in contact with the stopper in the step of positioning the position guiding member on the chuck plate on which the substrate is to be placed inside the apparatus for transporting a substrate.

The method may further comprise a step of storing a target position of the pair of support members of the apparatus for transporting a substrate when the position fixing member is in contact with the first guide pin provided on the chuck plate in the step of positioning the position guiding member on the chuck plate on which the substrate is to be placed inside the apparatus for transporting a substrate.

The method may further comprise a step of unloading the apparatus for transporting a substrate to the outside of the chamber; a step of removing the position guiding member from the apparatus for transporting a substrate, and disposing the substrate in the area from which the position guiding member is removed; and a step of loading the apparatus for transporting a substrate into the inside of the chamber, and moving the pair of support members to the target position.

### BRIEF DESCRIPTION OF THE DRAWINGS

FIG. 1 is a view showing a first body of a position guiding member according to an embodiment of the present disclosure.

FIG. 2 is a view showing a second body of a position guiding member according to an embodiment of the present disclosure.

FIG. 3 is a view showing a position guiding member according to an embodiment of the present disclosure.

FIG. 4 is a detailed view of a friction reducing member of FIG. 3.

FIG. 5 is a detailed view of a position fixing member of FIG. 3.

FIG. 6 is a view showing a portion of an apparatus for transporting a substrate according to an embodiment of the present disclosure.

FIG. 7 is a view showing a state in which an apparatus for transporting a substrate according to an embodiment of the present disclosure is aligned on a chuck plate.

FIG. 8 is a cross-sectional view of FIG. 7.

FIG. 9 is a view showing a method for position guiding of substrate according to an embodiment of the present disclosure.

### DETAILED DESCRIPTION

Hereinafter, some embodiments of the present disclosure will be described in detail with reference to exemplary drawings. It should be noted that, when reference numerals are added to components of each drawing, the same components have the same reference numeral even if displayed on different drawings. In addition, in describing the embodiment of the present disclosure, when it is determined that a detailed description of a related configuration or function interferes with the understanding of the embodiment of the present disclosure, the detailed description thereof will be omitted.

In the description of the embodiment according to the present disclosure, in the case of being described as being formed “on (above) or under (below)” of each element, it includes all that two elements are in direct contact with each other or are indirectly provided with other elements interposed therebetween. Also, if expressed as “on or under”, the meaning of the downward direction as well as the upward direction with respect to one element may be included.

In the present disclosure, a position guiding member having the same cross-sectional shape as that of a substrate is prepared, an apparatus for transporting a substrate on which the position guiding member is disposed is loaded into the inside of a chamber, a placing position of the position guiding member on a chuck plate inside the chamber is checked and stored, and then the substrate may be aligned at the above-described stored position when the substrate is disposed on the apparatus for transporting a substrate and the apparatus for transporting a substrate on which the substrate is disposed is loaded into the inside of the chamber.

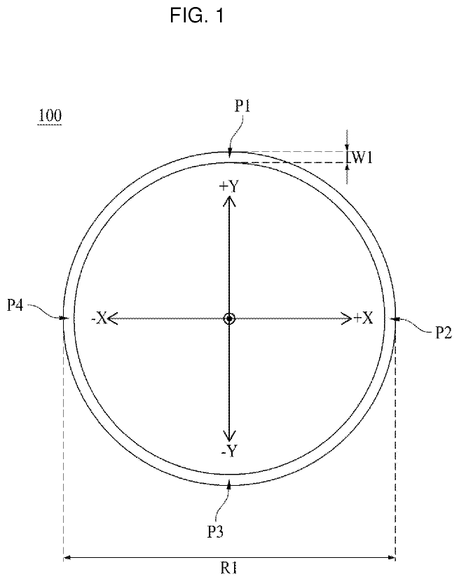

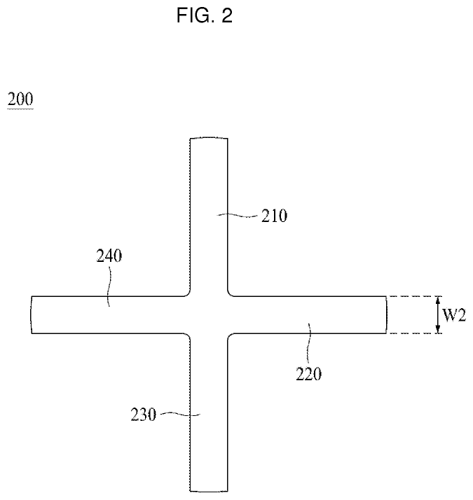

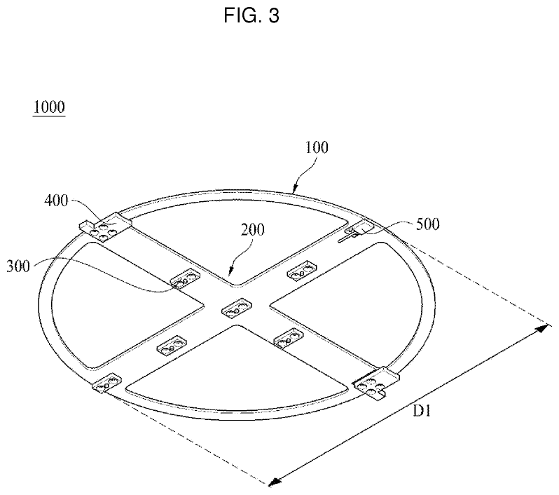

FIG. 1 is a view showing a first body of a position guiding member according to an embodiment of the present disclosure, FIG. 2 is a view showing a second body of a position guiding member according to an embodiment of the present disclosure, and FIG. 3 is a view showing a position guiding member according to an embodiment of the present disclosure. Hereinafter, a position guiding member according to an embodiment of the present disclosure will be described with reference to FIGS. 1 to 3.

The position guiding member according to an embodiment of the present disclosure includes a first body 100 and a second body 200, a plurality of friction reducing members 300 are provided on a first surface of the second body 200, and a plurality of position fixing members 400 and a capacitance sensor 500 may be provided on a first surface of an area where the first body 100 and the second body 200 meet.

Referring to FIG. 1, the first body 100 may have a circumferential shape and may have a first width (W1). The first body 100 may be formed of metal such as aluminum or a resin-based material, but it is not limited thereto.

The first width (W1) of the first body 100 has a width of a cross section and may have a constant thickness in the vertical direction. The first body 100 has the same cross-sectional shape as that of a substrate to be described later. Specifically, it means that a diameter of the first body 100 is the same as a diameter of the substrate. That is, in FIG. 1, the first body 100 has a first diameter (R1), and the diameter of the substrate may be the same as the first diameter (R1).

In addition, four points (P1 to P4) are illustrated in FIG. 1, which are provided to explain positions of the fixing member 400 and the capacitance sensor 500. The first point (P1) in the direction of 12 o'clock and the third point (P3) in the direction of 6 o'clock are positioned on the Y axis, and the second point (P2) in the direction of 3 o'clock and the fourth point (P4) in the direction of 9 o'clock are positioned on the X axis.

Referring to FIG. 2, the second body 200 has a second width (W2), and the material of the second body 200 may be the same as that of the first body 100. In FIG. 2, the second body 200 may include (2-1)th bodies 220 and 240 provided in the horizontal direction and (2-2)th bodies 210 and 230 provided in the vertical direction. The (2-1)th bodies 220 and 240 and the (2-2)th bodies 210 and 230 may intersect at their centers in a cross shape.

The (2-1)th bodies 220 and 240 may be provided in the X-axis direction of the first body 100, and the (2-2)th bodies 210 and 230 may be provided in the Y-axis direction of the first body 100.

The second bodies 210 to 240 connect the plurality of points of the first body 100, that is, the first to fourth points (P1 to P4). Specifically, the (2-1)th bodies 220 and 240 may connect the second point (P2) and the fourth point (P4) of the first body 100, and the (2-2)th bodies 210 and 230 may connect the first point (P1) and the third point (P3) of the first body 100.

In FIG. 3, the bottom surface of the position guiding member 1000 is illustrated, and the bottom surface having the friction reducing member 300, the position fixing member 400, and the capacitance sensor 500 may be referred to as the first surface. In addition, the direction in which the capacitance sensor 500 is provided may be the +Y direction in the direction of 12 o'clock in FIG. 1.

The plurality of friction reducing members 300 are provided on the first surface of the second body 200. When the position guiding member 1000 approaches a chuck plate as described later, the friction reducing members 300 may be provided to slide the position guiding member 1000 on the chuck plate so that it is possible to prevent the chuck plate and the rear surface of the position guiding member from colliding with each other and from being damaged.

In FIG. 3, the six friction reducing members 300 are shown, however, the friction reducing members 300 may be additionally provided on the rear surface of the position fixing member 400.

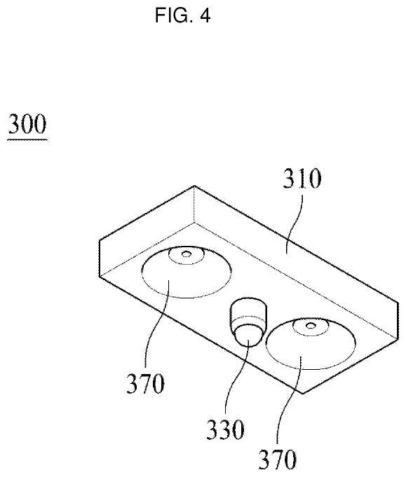

FIG. 4 is a detailed view of the friction reducing member of FIG. 3. Referring to FIG. 4, the friction reducing member 300 may include a reducing body 310, and a spherical member 330 inserted and exposed to a lower portion of the reducing body 310. In addition, although not shown in FIG. 4, an elastic member may be inserted into the inside of the reducing body.

In addition, first coupling members 370 are provided at both sides of the spherical member 330, and the first coupling member 370 may couple the reducing body 310 to the first surface of the second body 200 of the position guiding member 1000.

The spherical member 330 is provided in a ball type. When the position guiding member 1000 slides on the chuck plate, the spherical member 330 may be in direct contact with the chuck plate.

As the position fixing member 400 is provided on the edge of the position guiding member 1000, the position guiding member 1000 is in contact with a guide pin on the chuck plate to check an appropriate position of the position guiding member 1000.

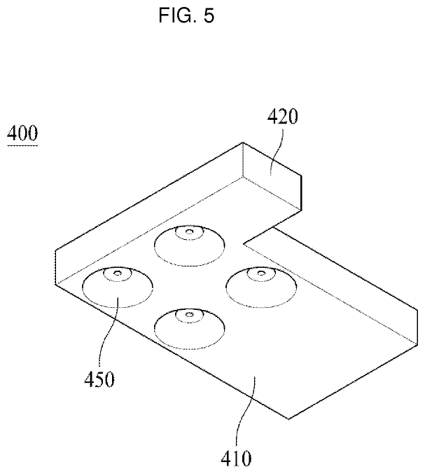

Referring to FIG. 5 showing the position fixing member in detail, the position fixing member 400 may include a fixing body 410, a protrusion 420 protruding from the fixing body 410, and a second coupling member 450 for coupling the fixing body 410 to the first body 100. In FIG. 5, the four of second coupling members 450 are shown, but not limited thereto.

In the position fixing member 400, the fixing body 410 overlaps the first body 100 of the position guiding member 1000 in the vertical direction, but the protrusion 420 protrudes in the outward direction of the first body 100 and does not overlap the first body 100 of the position guiding member 1000 in the vertical direction.

Referring to FIG. 3, a pair of position fixing members 400 are provided, and the protrusion of each position fixing member 400 protrudes out of the first body 100.

In addition, the pair of position fixing members 400 may be provided at the second point (P2) in the direction of 3 o'clock of the first body 100 and the fourth point (P4) in the direction of 9 o'clock of the first body 100, respectively. Specifically, the pair of position fixing members 400 may be disposed in an area where the first body 100 meets the (2-1)th bodies 220 and 240 of FIG. 2. Therefore, a first distance between the pair of position fixing members may be the same as the first diameter (R1) of the first body 100 described above. Also, in FIG. 3, since the first body 100 has a circumferential shape, a distance (D1) between the points where the first body 100 and the two of second bodies 200 meet may be the same as the first diameter (R1) of FIG. 1.

Also, the position guiding member 1000 includes the capacitance sensor 500, and the capacitance sensor 500 may be provided in one of areas where the first body 100 and the (2-2)th body meet. Referring to FIG. 1, the capacitance sensor 500 is disposed on the first point (P1) of the first body 100. Referring to FIGS. 1 and 2, the capacitance sensor may be disposed in the area where the first body 100 and the (2-2)th body 210 meet.

The above-described position guiding member 1000 is disposed on the apparatus for transporting a substrate, whereby the position guiding member 1000 may be used to check an appropriate position on which the substrate is to be placed on the chuck plate inside the chamber. The substrate may be a substrate used for manufacturing a semiconductor such as a silicon substrate, a silicon carbide substrate or a sapphire substrate.

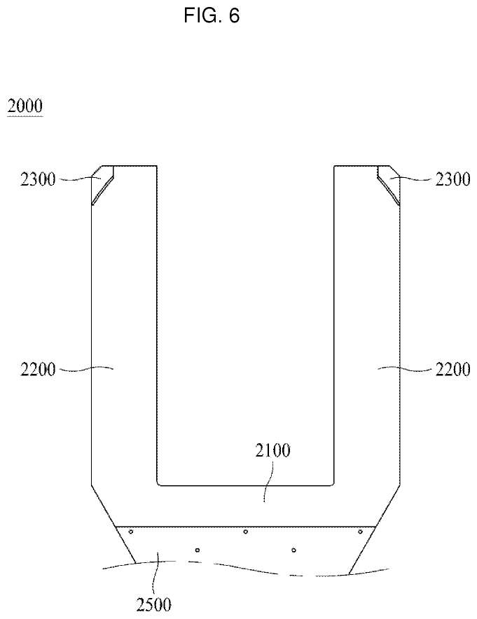

FIG. 6 is a view showing a portion of an apparatus for transporting a substrate according to an embodiment of the present disclosure. When the position guiding member 1000 of FIG. 3 is arranged on the configuration shown in FIG. 6, it may form the apparatus for transporting a substrate.

Referring to FIGS. 3 and 6, the apparatus for transporting a substrate according to an embodiment of the present disclosure may include a transporting robot 2500, an arm 2100 connected to the transporting robot 2500, a pair of support members 2200 connected to the arm 2100 and branched from the arm 2100 in order to support and transport the substrate, and a stopper 2300 provided on each of the support members 2200.

The position guiding member 1000 is provided on the configuration 2000 shown in FIG. 6, and more specifically, may be provided on the pair of support members 2200. In this case, the first surface of the first body and the second body constituting the position guiding member 1000 may be in contact with the upper surface of the support member 2200. That is, the first surface of the position guiding member 1000 may be disposed on the configuration 2000 of FIG. 6.

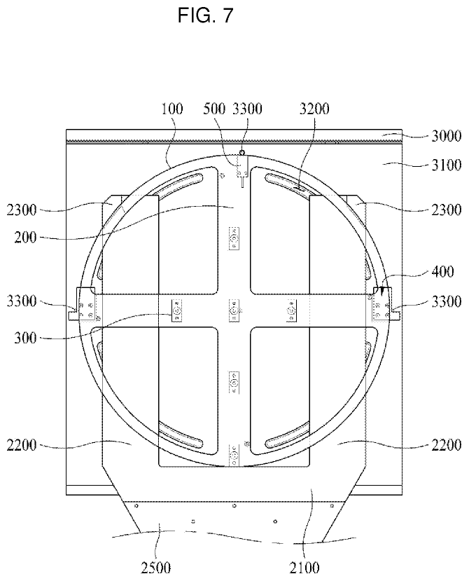

The stopper 2300 may extend from the arm 2100 and may be provided with a step above the support member 2200. Due to this configuration, the position guiding member 1000 stops at the stopper 2300 and is spaced a predetermined distance apart from the arm 2100 without colliding with the arm 2100. In FIG. 6, one stopper 2300 is provided at one end of each support member 2200, but it is not limited thereto. The stopper 2300 may be provided in a lower portion of each support member 2200. In this case, in FIG. 7, a pair of stoppers 2300 are provided on each support member 2200, whereby the position guiding member 1000 may be fixed at lower and upper sides with respect to FIG. 7.

Referring to FIGS. 1, 3, and 6, the capacitance sensor 500 provided in the position guiding member 1000 may be disposed in the direction of 12 o'clock in FIG. 6, and the capacitance sensor 500 may be provided in an area facing the transporting robot 2500 with respect to the arm 2100.

In addition, the (2-1)th bodies 220 and 240 of the second bodies in the position guiding member 1000 may be arranged in the direction for connecting the pair of support members 2200, that is, in the direction from the direction of 3 o'clock to the direction of 6 o'clock in FIG. 6.

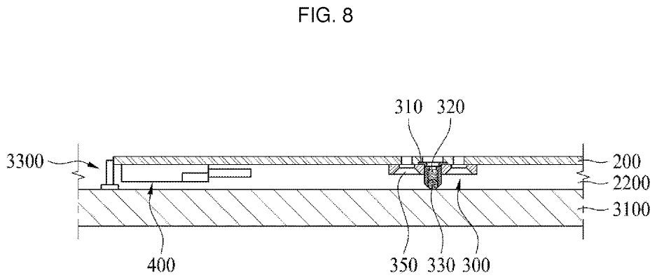

FIG. 7 is a view showing a state in which the apparatus for transporting a substrate according to an embodiment of the present disclosure is aligned on the chuck plate. FIG. 8 is a cross-sectional view of FIG. 7. Hereinafter, the state in which the apparatus for transporting a substrate according to an embodiment of the present disclosure is aligned on the chuck plate is explained with reference to FIGS. 7 and 8.

The chuck plate 3100 is a substrate supporter on which the substrate is to be disposed inside the chamber, and the chuck plate 3100 is provided with the plurality of guide pins 3300 capable of aligning the edges of the substrate. In the embodiment of the present disclosure, the four guide pins 3300 are provided. In addition, with reference to FIG. 7, a back plate protrudes upward from a lower portion of the chuck plate 3100, and the back plate 3000 may not necessarily protrude to the edge of the chuck plate 3100.

While the position guiding member 1000 is placed on the pair of support members 2200 in the apparatus for transporting a substrate, the apparatus for transporting a substrate is loaded into the chamber.

The apparatus for transporting a substrate may move from the direction of 6 o'clock to the direction of 12 o'clock with respect to FIG. 7. The protrusion formed in the position fixing members 400 provided in the position guiding member 1000 is in contact with the guide pin 3300 provided in the direction of 3 o'clock and the direction of 9 o'clock, respectively, whereby the apparatus for transporting a substrate may be stopped. In this case, the position of the position guiding member 1000 may be referred to as the appropriate position, and the substrate having the same edge shape as that of the position guiding member 1000 may be disposed at the appropriate position.

In FIG. 7, one guide pin 3300 may be provided in each of the direction of 12 o'clock and the direction of 6 o'clock. The guide pin 3300 provided in the direction of 6 o'clock may fix the substrate in the X-axis direction, that is, in the direction of 12 o'clock and the direction of 6 o'clock in FIG. 7.

For convenience, the guide pin in the direction of 3 o'clock and the direction of 9 o'clock may be referred to as a first guide pin, and the guide pin in the direction of 12 o'clock and the direction of 6 o'clock may be referred to as a second guide pin. Although not shown, the plurality of support pins are provided on the chuck plate, wherein the support pins directly support the substrate in the processing process to be described later, whereby the support pins may be different in function from the support pins surrounding the edge area of the substrate.

The chuck plate 3100 and the guide pin 3300 may be formed of a metal-based or resin-based material, and the back plate 3000 may be formed of a metal-based material. The capacitance sensor may be provided to sense a distance from an object without contact and may operate by forming an electric field between two electrodes. When the capacitance sensor 500 provided in the position guiding member 1000 approaches the back plate 3000 of the metal material in FIG. 7, the capacitance between the two electrodes is changed so that it is possible to check whether the guide pin 3300 is adjacent.

Therefore, even before the fixing members 400 are in contact with the pair of guide pins 3300, it is possible to check whether the position guiding member 1000 reaches the appropriate position by the action of the capacitance sensor 500.

In FIG. 7, a plurality of grooves 3200 are formed in the chuck plate 3100, and the number and shape of the grooves 3200 are not limited to the number and shape shown in the drawings.

Referring to FIG. 8, the approach of the position guiding member 1000 and the back plate 3000 may be sensed by the action of the capacitance sensor 500 before the second body 200 of the position guiding member 1000 contacts the guide pin 3300.

In addition, the friction reducing member 300 is provided on the first surface corresponding to the bottom surface of the second body 200, and the reducing body 310 is coupled to the first surface of the second body 200 through the first coupling member 370. When the position guiding member 1000 moves, the spherical member 330 is in contact with the chuck plate 3100. In this case, since the spherical member 330 is provided on an elastic member 320 such as spring, the spherical member 330 may be rotated while being moved in the upward direction of FIG. 8 when the spherical member 330 is in contact with the chuck plate 3100, whereby the position guiding member 1000 may move while sliding without colliding with the chuck plate 3100.

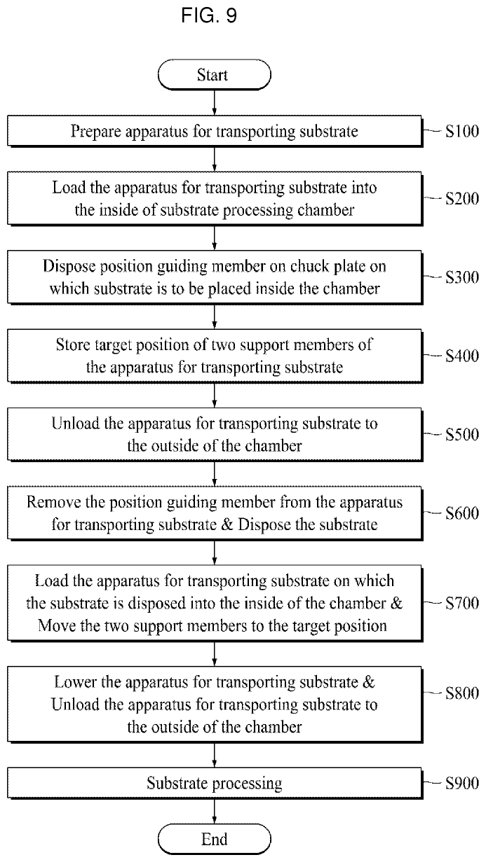

FIG. 9 is a view showing a method for position-guiding of substrate according to an embodiment of the present disclosure. Hereinafter, the method for position-guiding of substrate according to an embodiment of the present disclosure will be described with reference to FIG. 9.

First, the apparatus for transporting a substrate is prepared (S100). The apparatus for transporting a substrate is the same as that of the above-described embodiment. The position guiding member for guiding the placement position of the substrate may be disposed on the pair of support members connected to the arm, and repeated descriptions related to the configuration of the apparatus for transporting a substrate will be omitted.

In addition, the apparatus for transporting a substrate may be loaded into the substrate processing chamber (S200). The substrate processing chamber may be a drying chamber, but it may be a cleaning chamber or other chamber. The chuck plate on which the substrate is to be supported is provided inside the chamber. As described with reference to FIGS. 7 and 8, the plurality of guide pins are provided on the chuck plate, to thereby fix the substrate in the horizontal direction.

Then, the position guiding member may be positioned on the chuck plate on which the substrate is to be disposed inside the chamber (S300). That is, as described with reference to FIGS. 7 and 8, in a state in which the position guiding member is provided on the pair of support members in the apparatus for transporting a substrate, the position guiding member is positioned on the chuck plate, and the position of the position guiding member to be placed on the chuck plate may be checked by sensing the contact between the first guide pins and the position fixing member and the approach of the back plate and the capacitance sensor. In this case, when the position guiding member stops in the apparatus for transporting a substrate, the stopper is stopped while being in contact with the first body of the position guiding member, whereby the transporting robot and the arm may stop together.

A target position of the pair of support members in the apparatus for transporting a substrate is stored (S400). That is, in the step S300, it is preferable that the substrate is positioned at the position where the position guiding member is placed in the subsequent process, whereby the position where the position guiding member is placed is referred to as the ‘appropriate position’, and the ‘target position’ of the pair of support members is stored. Herein, when the position guiding member is positioned at the ‘appropriate position’, the position fixing member and the first guide pin provided on the chuck plate may be in contact with each other, and the position fixing member and the stopper may be in contact with each other.

In addition, the apparatus for transporting a substrate is unloaded from the chamber to the outside (S500), the position guiding member on the apparatus for transporting a substrate is removed in the outside of the chamber, and the substrate may be disposed at the same position (S600). Herein, the substrate may be a silicon substrate used as a material of a semiconductor device as described above.

In addition, the apparatus for transporting a substrate on which the above-described substrate is disposed is loaded into the chamber and the pair of support members are moved to the target position (S700). At this time, the pair of support members may move to the stored target position, and the substrate provided at the same position as that of the removed position guiding member may be placed at the position of the position guiding member in step S300.

In addition, the apparatus for transporting a substrate may be lowered and unloaded to the outside of the chamber (S800). That is, in a state in which the pair of support members of the apparatus for transporting a substrate support the substrate, if the height of the pair of support members is lowered and the support members are unloaded to the outside of the chamber, the substrate is supported by the support pins on the chuck plate and may not be moved.

Then, the processing process of the substrate in the chamber, for example, a drying process may be performed in the chamber (S900).

According to an embodiment of the present disclosure, the position guiding member, the apparatus for transporting a substrate including the same, and the method for position guiding of substrate are provided. The position guiding member having the same outer circumferential shape as that of the substrate is provided on the apparatus for transporting a substrate which transports the substrate into the inside of the chamber. The apparatus for transporting a substrate is inserted into the inside of the chamber, and the position guiding member is positioned at the position where the substrate is to be placed by the action of the guide pin on the chuck plate. In this case, after storing the appropriate position of the position guiding member, the substrate is placed in the apparatus for transporting a substrate instead of the position guide member and is loaded into the inside of the chamber, and then the support member is moved to the target position to allow the substrate on the support member to be placed at the accurate position, whereby the substrate does not collide with the guide pin or other components.

In the above description, even though all components constituting the embodiment of the present disclosure are combined into one or are operated in combination, the present disclosure is not necessarily limited to this embodiment. That is, within the scope of the purpose of the present disclosure, all components may be selectively combined and operated as one or more. Also, the terms such as “include”, “comprise”, or “have” as described above mean that the corresponding component may be inherent unless specifically opposed. Thus, it should be interpreted that other components may be further included rather than excluding other components. Unless otherwise defined, all terms including technical or scientific terms have the same meaning as commonly understood by a person skilled in the art to which the present invention belongs. Commonly used terms such as terms defined in advance should be interpreted as being consistent with the meaning in the context of the related technology and are not to be interpreted in an idealized or overly formal sense unless expressly so defined herein.

The above description is merely illustrative of the technical idea of the present invention, and various modifications and variations may be made by a person skilled in the art to which the present invention belongs without departing from the essential characteristics of the present invention. Therefore, the embodiments disclosed in the present invention are not intended to limit the technical idea of the present invention but to explain the technical idea of the present invention, and the scope of the technical idea of the present invention is not limited by these embodiments. The scope of the present disclosure should be construed on the basis of the claims, and all technical ideas within the scope equivalent to the claims should be construed as being included in the scope of the present disclosure.

What is claimed is:

1. A position guiding member comprising:
a first body having a first width of a circumferential shape;
a plurality of second bodies having a second width to connect facing points of the first body;
a plurality of friction reducing members provided on a first surface of the second body; and
a position fixing member provided in an area where the first body and the second body meet and provided with at least a portion protruding to the outside of the first body.

2. The position guiding member of claim 1, wherein the friction reducing member are provided on a first surface of the position fixing member.

3. The position guiding member of claim 1, wherein one pair of the position fixing members is provided, and a first distance between the pair of position fixing members is the same as a diameter of the first body.

4. The position guiding member of claim 3, wherein the plurality of second bodies include a (2-1)th body provided in the X-axis direction and a (2-2)th body provided in the Y-axis direction.

5. The position guiding member of claim 4, wherein the pair of position fixing members are respectively provided in areas where the first body and the (2-1)th body meet.

6. The position guiding member of claim 5, further comprising: a capacitance sensor provided in one area where the first body and the (2-2)th body meet.

7. The position guiding member of claim 1, wherein the plurality of friction reducing members include a reduction body, and a spherical member inserted into a lower portion of the reducing body and exposed thereto.

8. The position guiding member of claim 7, further comprising: an elastic member inserted into the inside of the reducing body.

9. The position guiding member of claim 7, further comprising: a first coupling member provided on both sides of the spherical member and configured to couple the reducing body to the first surface of the second body.

10. An apparatus for transporting a substrate comprising:
an arm connected to a transporting robot;
a pair of support members connected to the arm and configured to support and transport a substrate; and
a position guiding member provided on the support member,
wherein the position guiding member comprises a first body having a first width of a circumferential shape, a plurality of second bodies having a second width to connect facing points of the first body, a plurality of friction reducing members provided on a first surface of the second body, and a position fixing member provided in an area where the first body and the second body meet and provided with at least a portion protruding to the outside of the first body, and
wherein a first surface of a first body and a first surface of a second body in the position guiding member are in contact with an upper surface of the support member.

11. The apparatus of claim 10, wherein a stopper is provided in each of the pair of support members, and the first body of the position guiding member is in contact with the stopper.

12. The apparatus of claim 10, wherein a capacitance sensor, which is provided in one area where the first body and the (2-2)th body of the position guiding member meet, is provided on the first surface of the first body in an area facing the transporting robot.

13. The apparatus of claim 12, wherein the plurality of second bodies of the position guiding member include the (2-1)th body provided in the X-axis direction and the (2-2)th body provided in the Y-axis direction, and the (2-1)th body is disposed in a direction connecting the pair of support members.

14. A method for position guiding of substrate comprising:
a step of preparing an apparatus for transporting a substrate in which a position guiding member for guiding a placement position of a substrate is disposed on a pair of support members connected to an arm;
a step of loading the apparatus for transporting a substrate into a substrate processing chamber; and
a step of positioning the position guiding member on a chuck plate on which the substrate is to be placed inside the chamber,
wherein the position guiding member includes a first body having a first width of a circumferential shape corresponding to an edge area of the substrate, and a position fixing member provided on a first surface of the first body and provided with at least a portion protruding to the outside of the first body, and
a first guide pin provided on the chuck plate is in contact with the position fixing member in the step of positioning the position guiding member on the chuck plate on which the substrate is to be placed inside the apparatus for transporting a substrate.

15. The method of claim 14, wherein one pair of the position fixing members is provided, and the position fixing members and the first guide pins provided on the chuck plate are in contact with each other on both sides of the area on which the substrate is to be placed in the step of positioning the position guiding member on the chuck plate on which the substrate is to be placed inside the apparatus for transporting a substrate.

16. The method of claim 15, wherein a plurality of friction reducing members are provided on a rear surface of the guide member, and the position guiding member slides on the chuck plate to bring the friction reducing members into contact with the chuck plate in the step of positioning the position guiding member on the chuck plate on which the substrate is to be placed inside the apparatus for transporting a substrate.

17. The method of claim 16, wherein the plurality of friction reducing members include a reducing body and a spherical member inserted to a lower portion of the reducing body and exposed thereto, and the spherical member is in contact with the chuck plate when the position guiding member slides on the chuck plate.

18. The method of claim 14, wherein the position guiding member further includes a capacitance sensor provided at the foremost side of the first body, and the capacitance sensor senses a back plate provided on a lower portion of the chuck plate in the step of positioning the position guiding member on the chuck plate on which the substrate is to be placed inside the apparatus for transporting a substrate.

19. The method of claim 14, wherein a stopper is provided in each of the pair of support members of the apparatus for transporting a substrate, and the first body of the position guiding member is in contact with the stopper in the step of positioning the position guiding member on the chuck plate on which the substrate is to be placed inside the apparatus for transporting a substrate.

20. The method of claim 19, further comprising: a step of storing a target position of the pair of support members of the apparatus for transporting a substrate when the position fixing member is in contact with the first guide pin provided on the chuck plate in the step of positioning the position guiding member on the chuck plate on which the substrate is to be placed inside the apparatus for transporting a substrate.
